(19) United States
(12) Patent Application Publication
(10) Pub. No.: US 2024/0068101 A1
(43) Pub. Date: Feb. 29, 2024

(54) SUBSTRATE PROCESSING APPARATUS

(71) Applicant: Tokyo Electron Limited, Tokyo (JP)

(72) Inventor: Yasushi TAKEUCHI, Iwate (JP)

(21) Appl. No.: 18/364,010

(22) Filed: Aug. 2, 2023

(30) Foreign Application Priority Data
Aug. 25, 2022 (JP) 2022-134278

(51) Int. Cl. C23C 16/458; H01L 21/687

(52) U.S. Cl. CPC C23C 16/4584; H01L 21/68742; H01L 21/68764

(57) ABSTRACT

A substrate processing apparatus includes a vacuum chamber, a rotary table rotatably provided in the vacuum chamber, a stage having a mounting surface on which a substrate is mounted at a position spaced apart from a rotation center of the rotary table, a lift pin configured to be displaced relative to the stage through a through-hole of the stage to raise and lower the substrate, and a gas suctioning section configured to apply a suction force to the substrate via the through-hole when the lift pin is being lowered. The stage includes a groove on the mounting surface, the groove communicating with the through-hole and extending from the through-hole toward a center of the stage.

### CROSS-REFERENCE TO RELATED APPLICATIONS

This patent application is based on and claims priority to Japanese Patent Application No. 2022-134278 filed on Aug. 25, 2022, the entire contents of which are incorporated herein by reference.

### TECHNICAL FIELD

The present disclosure relates to a substrate processing apparatus.

### BACKGROUND

Patent Document 1 discloses a substrate processing apparatus including a rotary table that is rotatable in a vacuum chamber, and multiple stages that are rotatable relative to the rotary table and that are configured to mount substrates thereon. The substrate processing apparatus performs processing of depositing a film on each mounted substrate by supplying a processing gas into the processing chamber while rotating the rotary table and each of the multiple stages, for example.

In this type of substrate processing apparatus, when the substrate is mounted on the stage, the substrate is suctioned through one through-hole among multiple through-holes provided in the stage to raise and lower the lift pins, and the substrate is fixed to the surface of the stage.

### RELATED ART DOCUMENT

### Patent Document

[Patent Document 1] Japanese Laid-open Patent Application Publication No. 2021-110023

### SUMMARY

According to an aspect of the present disclosure, a substrate processing apparatus includes a vacuum chamber, a rotary table rotatably provided in the vacuum chamber, a stage having a mounting surface on which a substrate is mounted at a position spaced apart from a rotation center of the rotary table, a lift pin configured to be displaced relative to the stage through a through-hole of the stage to raise and lower the substrate, and a gas suctioning section configured to apply a suction force to the substrate via the through-hole when the lift pin is being lowered. The stage includes a groove on the mounting surface, the groove communicating with the through-hole and extending from the through-hole toward a center of the stage.

### BRIEF DESCRIPTION OF THE DRAWINGS

FIG. 1 is a vertical cross-sectional view illustrating a configuration example of a film deposition apparatus according to an embodiment;

FIG. 2 is a plan view illustrating a configuration in a vacuum chamber of the film deposition apparatus of FIG. 1;

FIG. 3 is a perspective view illustrating a configuration of a rotary table and a stage of the film deposition apparatus of FIG. 1;

FIG. 4 is an enlarged partial cross-sectional view illustrating a vicinity of the stage and the lift pin mechanism of FIG. 1;

FIG. 5A is a plan view of a stage;

FIG. 5B is a cross-sectional view taken along the line VB-VB of FIG. 5A;

FIG. 5C is a diagram illustrating a distribution of a suction force on a mounting surface of the stage;

FIG. 6A is a plan view of a stage according to a first modified example;

FIG. 6B is a diagram illustrating a distribution of a suction force of the stage of FIG. 6A;

FIG. 6C is a plan view of a stage according to a second modified example;

FIG. 6D is a diagram illustrating a distribution of a suction force of the stage of FIG. 6C;

FIG. 7A is a plan view of a stage according to a third modified example;

FIG. 7B is a plan view of a stage according to a fourth modified example; and

FIG. 7C is a plan view of a stage according to a fifth modified example.

### DETAILED DESCRIPTION OF EMBODIMENTS

In the following, embodiments of the present disclosure will be described with reference to the drawings. In the drawings, the same components are denoted by the same reference symbols, and duplicated description may be omitted.

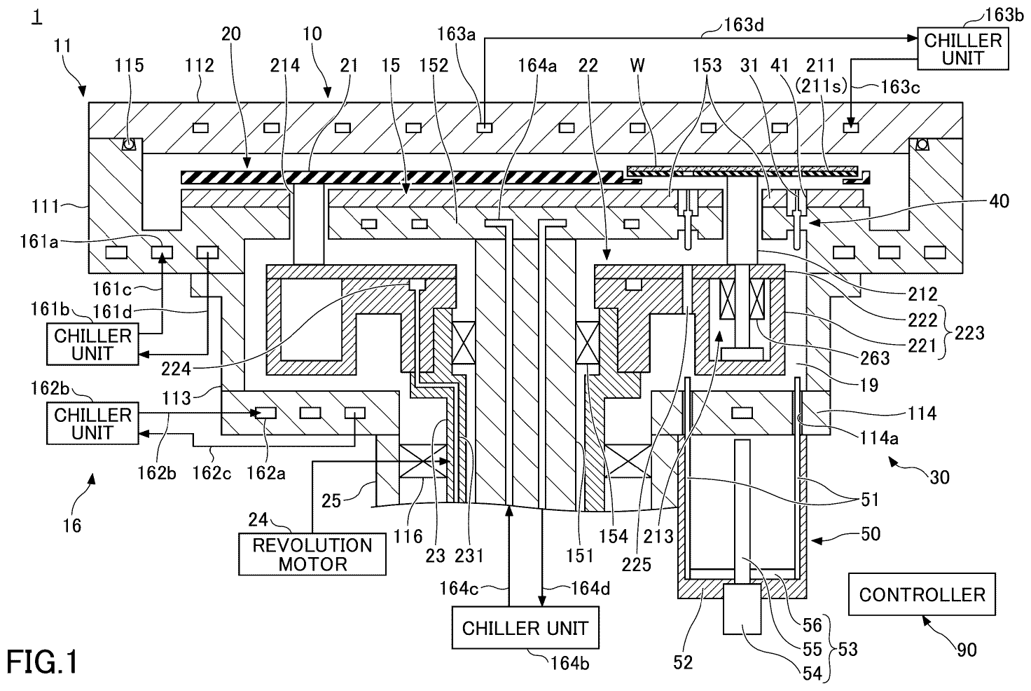

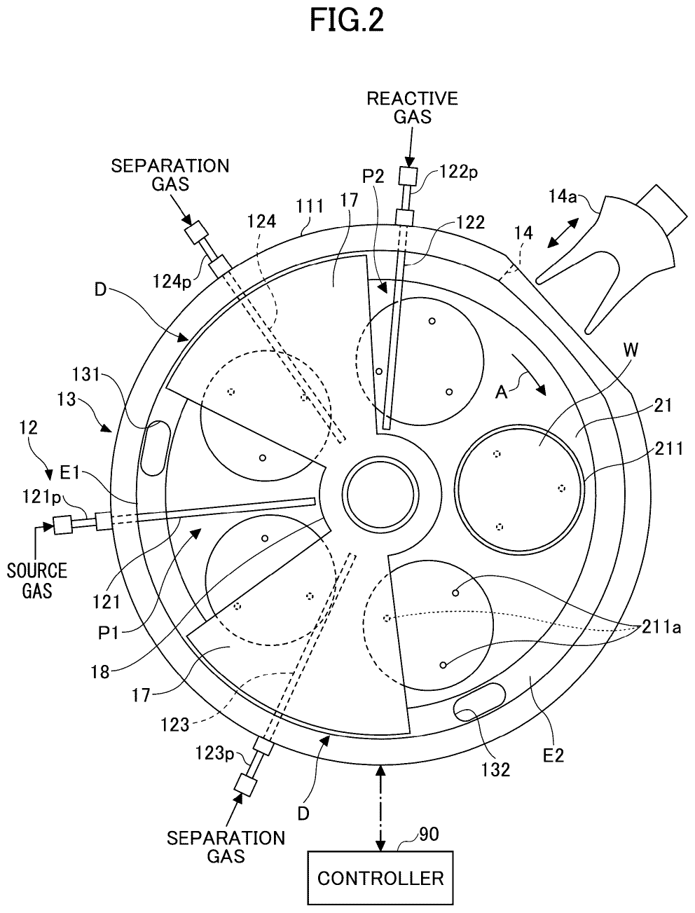

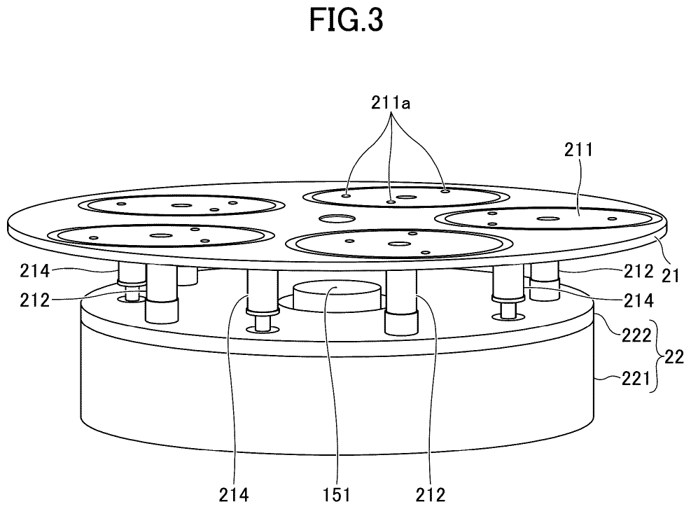

A film deposition apparatus 1 that forms a film on a substrate W, which is an example of a substrate processing apparatus, will be described with reference to FIGS. 1 to 3. FIG. 1 is a vertical cross-sectional view illustrating a configuration example of the film deposition apparatus 1 according to an embodiment. FIG. 2 is a plan view illustrating a configuration in a vacuum chamber 11 of the film deposition apparatus 1 in FIG. 1. Here, in FIG. 2, a top plate is not illustrated for convenience of explanation. FIG. 3 is a perspective view illustrating a configuration of a rotary table 21 and a stage 211 of the film deposition apparatus 1 in FIG. 1.

The film deposition apparatus 1 includes a processing section 10, a rotary drive device 20, a lift pin mechanism 30, and a controller 90.

The processing section 10 performs a film deposition process of depositing a film on the substrate W. The processing section 10 includes the vacuum chamber 11, a gas introduction section 12, a gas exhaust section 13, a transfer port 14, a heating section 15, and a cooling section 16.

The vacuum chamber 11 is a processing chamber that can reduce a pressure in an inner space thereof. The vacuum chamber 11 is formed in a flat housing having a substantially circular shape as a planar shape, and can accommodate multiple substrates W in the internal space. The substrate W may be, for example, a semiconductor wafer. The vacuum chamber 11 includes a main body 111, a top plate 112, a sidewall body 113, and a bottom plate 114 (FIG. 1). The main body 111 has a cylindrical shape. The top plate 112 is detachably disposed on the upper surface of the main body 111. The main body 111 and the top plate 112 are airtightly sealed by a seal 115. The sidewall body 113 has a cylindrical shape and is airtightly connected to the lower surface of the main body 111. The bottom plate 114 is air-tightly connected to the bottom surface of the sidewall body 113.

The gas introduction section 12 includes a source gas nozzle 121, a reactive gas nozzle 122, and separation gas nozzles 123 and 124 (FIG. 2). The source gas nozzle 121, the reactive gas nozzle 122, and the separation gas nozzles 123 and 124 are disposed above the rotary table 21, which will be described later, spaced apart from each other along a circumferential direction of the vacuum chamber 11 (a direction indicated by an arrow A in FIG. 2). In the illustrated example, the separation gas nozzle 123, the source gas nozzle 121, the separation gas nozzle 124, and the reactive gas nozzle 122 are disposed in this order in a clockwise direction (a rotation direction of the rotary table 21) from the transfer port 14. The source gas nozzle 121, the reactive gas nozzle 122, and the separation gas nozzles 123 and 124 respectively have gas introduction ports 121p, 122p, 123p, and 124p for introducing various gases at base ends thereof (FIG. 2). The gas introduction ports 121p, 122p, 123p, and 124p are fixed to a sidewall of the main body 111 and protrude to the outside of the main body 111. The source gas nozzle 121, the reactive gas nozzle 122, and the separation gas nozzles 123 and 124 are inserted into the vacuum chamber 11 from the sidewall of the main body 111 and extend inward in the radial direction of the main body 111. The source gas nozzle 121, the reactive gas nozzle 122, and the separation gas nozzles 123 and 124 are made of, for example, quartz, and are disposed in parallel to the rotary table 21.

The source gas nozzle 121 is connected to a source gas supply (which is not illustrated) via a pipe, a flow rate controller, and the like (which are not illustrated). As the source gas, for example, a silicon-containing gas or a metal-containing gas may be used. In the source gas nozzle 121, multiple discharge holes (which are not illustrated) opened toward the rotary table 21 are arranged at intervals along the axial direction of the source gas nozzle 121. A region below the source gas nozzle 121 becomes a source gas adsorption region P1 for adsorbing the source gas onto the substrate W.

The reactive gas nozzle 122 is connected to a reactive gas supply (which is not illustrated) via a pipe, a flow rate controller, and the like (which are not illustrated). As the reactive gas, for example, an oxidizing gas or a nitriding gas can be used. In the reactive gas nozzle 122, multiple discharge holes (which are not illustrated) opened toward the rotary table 21 are arranged at intervals along the axial direction of the reactive gas nozzle 122. A region below the reactive gas nozzle 122 becomes a reactive gas supply region P2 in which the source gas adsorbed on the substrate W in the source gas adsorption region P1 is oxidized or nitrided. In the present embodiment, the processing gas for processing the substrate W corresponds to the source gas and the reactive gas described above.

Each of the separation gas nozzles 123 and 124 is connected to a separation gas supply (which is not illustrated) via a pipe, a flow rate control valve, and the like (which are not illustrated). As the separation gas, for example, an inert gas such as argon (Ar) gas or nitrogen gas (N₂) gas can be used. In the separation gas nozzles 123 and 124, multiple discharge holes (which are not illustrated) opened toward the rotary table 21 are arranged at intervals along the axial direction of each of the separation gas nozzles 123 and 124.

Additionally, as illustrated in FIG. 2, two protruding portions 17 are provided in the vacuum chamber 11. In order to form separation regions D together with the separation gas nozzles 123 and 124, the protruding portion 17 is attached to the back surface of the top plate 112 so as to protrude toward the rotary table 21. Each protruding portion 17 has a fan shape whose top portion is cut in an arc shape as a planar shape, and is disposed such that the inner arc is connected to a protrusion 18 and the outer arc is along the sidewall of the vacuum chamber 11.

The gas exhaust section 13 includes a first exhaust port 131 and a second exhaust port 132 (FIG. 2). The first exhaust port 131 is formed at the bottom of a first exhaust region E1 communicating with the source gas adsorption region P1. The second exhaust port 132 is formed at the bottom of a second exhaust region E2 communicating with the reactive gas supply region P2. The first exhaust port 131 and the second exhaust port 132 are connected to an exhaust device (which is not illustrated) via an exhaust pipe (which is not illustrated).

The transfer port 14 is provided in the sidewall of the main body 111 (FIG. 2). At the transfer port 14, the substrate W is transferred between the rotary table 21 inside the vacuum chamber 11 and a transfer arm 14a outside the vacuum chamber 11. The transfer port 14 is opened and closed by a gate valve (which is not illustrated).

The heating section 15 includes a fixing shaft 151, a heater support 152, and a heater 153 (FIG. 1).

The fixing shaft 151 has a columnar shape having the center of the vacuum chamber 11 as a central axis. The fixing shaft 151 is provided to pass through the bottom plate 114 of the vacuum chamber 11 on the inner side of a rotary shaft 23 of the rotary drive device 20, which will be described later.

The heater support 152 is fixed to an upper portion of the fixing shaft 151 and has a disc shape. The heater support 152 supports the heater 153.

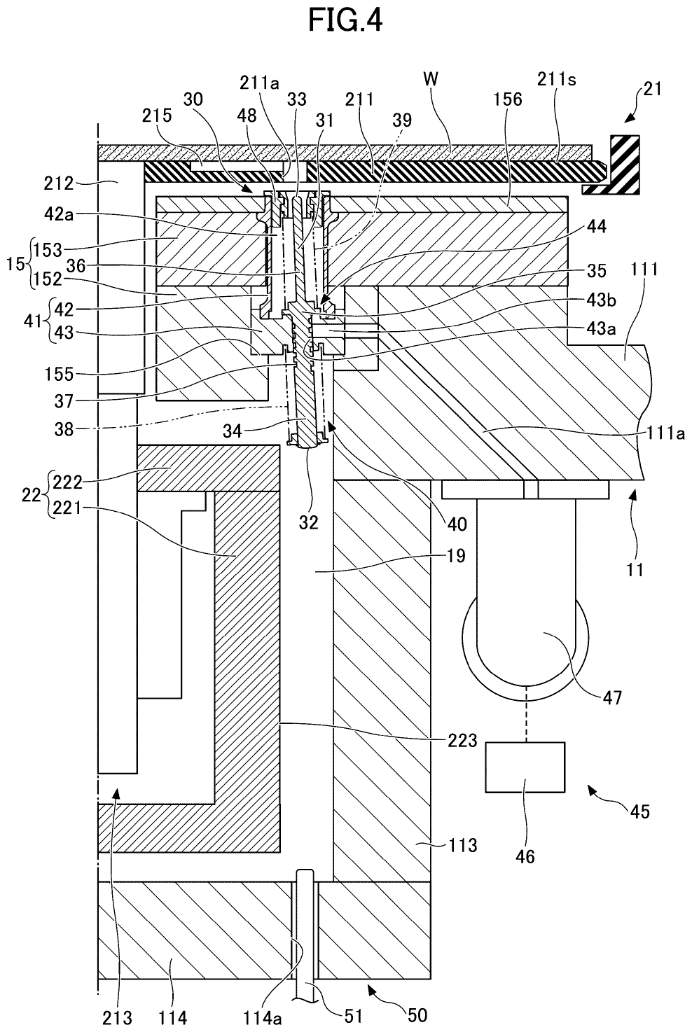

The heater 153 is provided on an upper surface of the heater support 152. The heater 153 may be provided on the main body 111 in addition to the upper surface of the heater support 152. The heater 153 generates heat by electric power being supplied from a power supply (which is not illustrated) and heats the substrate W. Additionally, a shielding plate 156 (see FIG. 4) is provided on an upper surface of the heater 153. The shielding plate 156 is disposed above the main body 111 or the heater support 152 to face the main body 111 or the heater support 152 and to prevent the heater 153 from being exposed to the processing gas.

The cooling section 16 includes fluid flow paths 161a to 164a, chiller units 161b to 164b, inlet pipes 161c to 164c, and outlet pipes 161d to 164d (FIG. 1). The fluid flow paths 161a to 164a are formed inside the main body 111, the top plate 112, the bottom plate 114, and the heater support 152. The chiller units 161b to 164b output temperature control fluid. The temperature control fluid output from the chiller units 161b to 164b flows and circulates through the inlet pipes 161c to 164c, the fluid flow paths 161a to 164a, and the outlet pipes 161d to 164d in this order. This allows the temperatures of the main body 111, the top plate 112, the bottom plate 114, and the heater support 152 to be adjusted. As the temperature control fluid, for example, water or a fluorine-based fluid such as Galden (registered trademark) can be used.

The rotary drive device 20 includes the rotary table 21, an accommodation box 22, the rotary shaft 23, a revolution motor 24, and an outer cylinder 25.

The rotary table 21 is provided in the vacuum chamber 11 and has a rotation center at the center of the vacuum chamber 11. The rotary table 21 has, for example, a disk shape and is made of quartz. Multiple (for example, five) stages 211 are provided on an upper surface of the rotary table 21 along the rotation direction (the circumferential direction). The rotary table 21 is connected to the accommodation box 22 via a connection 214 (FIG. 3).

Each stage 211 has a disk shape slightly larger than the substrate W and is made of, for example, quartz. A mounting surface 211s on which the substrate W is mounted is formed on an upper surface of each stage 211. Each stage 211 is connected to a rotation motor 213 via a rotation shaft 212 and is configured to be rotatable relative to the rotary table 21 (FIG. 1).

The rotation shaft 212 connects a lower surface of the stage 211 and the rotation motor 213 accommodated in the accommodation box 22, and transmits the power of the rotation motor 213 to the stage 211. The rotation shaft 212 is configured to be rotatable around the center of the stage 211. The rotation shaft 212 is provided to pass through a ceiling 222 of the accommodation box 22 and the rotary table 21. A seal 263 is provided in the vicinity of the penetration portion of the ceiling 222 of the accommodation box 22, and an airtight state in the accommodation box 22 is maintained. The seal 263 includes, for example, a magnetic fluid seal.

The rotation motor 213 rotates the stage 211 via the rotation shaft 212 relative to the rotary table 21 to rotate the substrate W around the center of the substrate W. For the rotation motor 213, a servomotor is preferably applied, for example.

The connection 214 connects the lower surface of the rotary table 21 and the upper surface of the accommodation box 22 (FIG. 3). Multiple connections 214 are provided along the circumferential direction of the rotary table 21.

The accommodation box 22 is provided below the rotary table 21 inside the vacuum chamber 11. The accommodation box 22 is connected to the rotary table 21 via the connection 214 and rotates together with the rotary table 21. The accommodation box 22 may be configured to be movable up and down inside the vacuum chamber 11 by a raising/lowering mechanism (which is not illustrated). The accommodation box 22 includes a main body 221 and the ceiling 222.

The main body 221 is formed in a U-shape in a vertical cross-sectional view, and is formed in a ring shape along the rotation direction of the rotary table 21 (FIG. 1).

The ceiling 222 is provided on the upper surface of the main body 221 so as to cover an opening of the main body 221. With this, the main body 221 and the ceiling 222 form a rotation accommodating section 223 separated from the inside of the vacuum chamber 11.

The rotation accommodating section 223 is formed in a rectangular shape in a vertical cross-sectional view, and has a ring shape along the rotation direction of the rotary table 21. The rotation accommodating section 223 accommodates the rotation motor 213 (a rotation source). In the main body 221, a communication path 224 is formed to allow the rotation accommodating section 223 to communicate with the outside of the film deposition apparatus 1. This allows the atmosphere to be introduced into the rotation accommodating section 223 from the outside of the film deposition apparatus 1, and the inside of the rotation accommodating section 223 is cooled and maintained at the atmospheric pressure. In order to rotatably arrange the rotation accommodating section 223, the vacuum chamber 11 has a rotation source accommodating space 19 surrounded by the sidewall body 113, the bottom plate 114, and the heating section 15.

The rotary shaft 23 is fixed to a lower portion of the accommodation box 22. The rotary shaft 23 is provided to pass through the bottom plate 114 of the vacuum chamber 11. The rotary shaft 23 transmits the power of the revolution motor 24 to the rotary table 21 and the accommodation box 22 to integrally rotate the rotary table 21 and the accommodation box 22. A seal 154 is provided between an outer wall of the fixing shaft 151 and an inner wall of the rotary shaft 23 of the rotary drive device 20. This allows the rotary shaft 23 to rotate with respect to the fixing shaft 151 while maintaining the airtight state in the vacuum chamber 11. A magnetic fluid seal can be applied to the seal 154, for example.

The outer cylinder 25 of the rotary drive device 20 is connected to a lower surface of the bottom plate 114 of the vacuum chamber 11 on the center side. The outer cylinder 25 supports the vacuum chamber 11 together with the fixing shaft 151 of the vacuum chamber 11. A seal 116 is provided between the rotary shaft 23 and the outer cylinder 25 to maintain an airtight state in the vacuum chamber 11. A magnetic fluid seal can be applied to the seal 116, for example.

A path 231 is formed inside the rotary shaft 23. The path 231 is connected to the communication path 224 of the accommodation box 22 and functions as a fluid flow path for introducing the atmosphere into the accommodation box 22. Additionally, the path 231 functions as a wiring duct for introducing a power line and a signal line for driving the rotation motor 213 into the accommodation box 22. The paths 231 are provided such that the number of the paths 231 is equal to the number of the rotation motors 213, for example.

Additionally, as illustrated in FIG. 1, when the transfer arm 14a (FIG. 2) carries the substrate W to and from the stage 211, the lift pin mechanism 30 raises and lowers multiple (three in the present embodiment) lift pins 31 to receive and deliver the substrate W from and to the transfer arm 14a. The film deposition apparatus 1 includes the lift pin mechanism 30 directly below a downward-facing position of the stage 211 that is adjacent to the transfer port 14. The lift pin mechanism 30 includes, in the vacuum chamber 11, multiple (three) upper lift parts 40 each having multiple lift pins 31, and one lower operation part 50 that simultaneously raises the multiple lift pins 31 and simultaneously lowers the multiple lift pins 31.

The upper lift parts 40 are installed so as to pass through the heater support 152 and the heater 153, and accommodate the lift pins 31 in a displaceable manner. The lower operation part 50 is attached to the lower surface of the bottom plate 114 of the vacuum chamber 11. The lower operation part 50 includes multiple (three) plungers 51 that are displaced along the vertical direction to respectively press the lower ends of the lift pins 31. That is, the lift pin mechanism 30 has a two stage structure in which multiple lift pins 31 that directly contact the substrate W and multiple plungers 51 that indirectly raise and lower the substrates W via the lift pins 31 are included as operating members and are vertically separated from each other.

The lower operation part 50 includes a housing 52 and a plunger drive section 53 in addition to the plungers 51. Additionally, the plunger drive section 53 includes a drive source 54, a drive transmitter 55 that transmits an operation force of the drive source 54, and a movable body 56 that supports each plunger 51 and is displaced in the housing 52 by the drive transmitter 55.

The housing 52 is fixed to the bottom plate 114 at a side of the outer cylinder 25, and is formed in an appropriate shape in which each component of the lower operation part 50 can be accommodated. The drive source 54 is provided at the lower end of the housing 52, operates based on the control of the controller 90, and transmits the operating force to the drive transmitter 55. The drive transmitter 55 raises and lowers the movable body 56 in the vertical direction by appropriately reducing or converting the operating force of the drive source 54. The movable body 56 extends outward in the radial direction (horizontally) from the drive transmitter 55 and supports a lower end of each plunger 51. The movable body 56 is raised or lowered in the vertical direction by the drive transmitter 55, and thus displaces each plunger 51 together.

Each plunger 51 is formed in an elongated solid rod shape, is fixed to the movable body 56, and extends parallel in the vertical direction. Bottom plate side through-holes 114a through which the respective plungers 51 pass are formed in portions of the bottom plate 114 facing the respective plungers 51. Additionally, box side through-holes 225 that penetrate the accommodation box 22 and from which the respective plungers 51 pass are formed in portions of the accommodation box 22 that face the respective plungers 51 in an area closer to the rotary shaft 23.

FIG. 4 is an enlarged partial cross-sectional view illustrating a vicinity of a location where the lift pin mechanism 30 of FIG. 1 is provided. As illustrated in FIG. 4, each of the plungers 51 stands by in a state in which the upper end slightly protrudes from the bottom plate side through-hole 114a in the non-operating state of the lift pin 31. When the substrate W is received or delivered, each plunger 51 is raised together with the movable body 56 and moves in the rotation source accommodating space 19. Each plunger 51 passes through the side of the accommodation box 22 or the box side through-hole 225 and comes into contact with the lift pin 31 of each upper lift part 40 to push up the lift pin 31.

Each upper lift part 40 includes the lift pin 31, an accommodating part 41 that accommodates the lift pin 31 such that the lift pin 31 can be raised and lowered, a gas suctioning section 45 configured to supply and exhaust a gas through the accommodating part 41, and a cylindrical member 48 that is disposed at an upper end of the accommodating part 41 and that is simultaneously displaceable with the lift pin 31.

The multiple (three) upper lift parts 40 are provided on the side of the rotation shaft 212 and are provided along the circumferential direction of the stage 211. The stage 211 includes multiple (three) through-holes 211a through which the lift pins 31 can pass, corresponding to the positions where the upper lift parts 40 are disposed (see also FIG. 2). The through-holes 211a are disposed at equal intervals along the circumferential direction of the stage 211 at positions spaced apart from the center of the stage 211 by a predetermined radius.

The lift pin 31 is a member having a cylindrical shape, and is disposed in the accommodating part 41, so that the lift pin 31 is displaceable between a lowered position at which a lower end surface 32 protrudes downward from a lower surface of the heater support 152 and a raised position at which an upper end surface 33 protrudes upward from an upper surface of the stage 211. Additionally, each lift pin 31 is inclined so that the upper end side approaches the rotary shaft 23 (the revolution shaft) side of the rotary table 21. Here, the lift pins 31 may be arranged in parallel with the vertical direction. The lift pin 31 includes a lower rod portion 34, a flange forming portion 35, and an upper rod portion 36 in this order from the lower side to the upper side. The lower rod portion 34, the flange forming portion 35, and the upper rod portion 36 are integrally formed with one another.

The circumferential surface of the lower rod portion 34 has a smooth circumferential surface without unevenness in a range from the lower end surface 32 to the intermediate portion of the lower rod portion 34, and has an uneven surface in which a spiral groove 37 is formed in a range from the intermediate portion of the lower rod portion 34 to the flange forming portion 35. The spiral groove 37 forms a flow path through which a gas flows in a state where the lift pin 31 is raised from the lowered position.

Additionally, the lift pin 31 is elastically pressed downward by a lower coil spring 38. The flange forming portion 35 regulates the lowering of the lift pin 31 from the accommodating part 41. A lower end of an upper coil spring 39 is in contact with an upper surface of the flange forming portion 35. An upper end of the upper coil spring 39 is in contact with the cylindrical member 48. With this, the upper coil spring 39 elastically supports the cylindrical member 48.

The upper rod portion 36 of the lift pin 31 is formed to be thinner than the lower rod portion 34 and forms a portion for supporting the substrate W. The upper end surface 33 of the lift pin 31 continuous to the upper rod portion 36 is formed in a substantially hemispherical shape and can be brought into point contact with the substrate W.

The accommodating part 41 that accommodates the lift pin 31 includes an accommodating bracket 42 disposed to pass through the heater 153 and a support bracket 43 that supports a lower portion of the accommodating bracket 42 and that is fixed to the heater support 152. The support bracket 43 is accommodated in a recessed space 155 formed in the heater support 152 and supports the accommodating bracket 42.

The support bracket 43 includes an arrangement hole 43a in which the lower rod portion 34 of the lift pin 31 is arranged. The arrangement hole 43a extends with a constant inner diameter, and its axial center is inclined with respect to the vertical direction. That is, the lower rod portion 34 comes into contact with the inner surface of the support bracket 43 forming the arrangement hole 43a, so that the lift pin 31 can be raised and lowered while maintaining the inclined posture.

Additionally, the support bracket 43 includes a gas communication hole 43b that communicates between the outer surface of the support bracket 43 and the arrangement hole 43a. The gas communication hole 43b extends in the horizontal direction and forms a part of the gas suctioning section 45 that causes the gas to flow toward the arrangement hole 43a.

The gas suctioning section 45 fixes the substrate W to the stage 211 by suctioning the gas when the lift pin 31 is being lowered. Specifically, the gas suctioning section 45 includes a suction pump 46 provided outside the vacuum chamber 11, a connection pipe 47 connected to an outer peripheral portion of the vacuum chamber 11, and a gas path 111a provided in the vacuum chamber 11. Additionally, the connection pipe 47 is provided with an open/close valve that opens and closes a flow path of the connection pipe 47, a mass flow controller that controls a flow rate of gas (both are not illustrated), and the like under the control of the controller 90. The gas path 111a is provided in the main body 111 and the heater support 152 and communicates with the gas communication hole 43b provided in the support bracket 43.

Additionally, the cylindrical member 48 of the upper lift part 40 is formed in a cylindrical shape disposed at an upper portion of the accommodating part 41 and inside the accommodating part 41, and the lift pin 31 is disposed inside the cylindrical member 48. The cylindrical member 48 is provided so as to be movable relative to the accommodating part 41, and is pushed upward via the upper coil spring 39 when the lift pin 31 is raised, so that the cylindrical member 48 is raised together with the lift pin 31. The cylindrical member 48 is brought into contact with the back surface of the stage 211 with being raised, so that the through-hole 211a of the stage 211 and the accommodation space 42a of the accommodating part 41 communicate with each other. When the cylindrical member 48 comes into contact with the stage 211, the raising of the cylindrical member 48 is stopped, and the lift pins 31 continue to be raised relative to the cylindrical member 48. With this, the lift pin 31 is stably inserted into the through-hole 211a.

Returning back to FIG. 1, the controller 90 controls each component of the film deposition apparatus 1. The controller 90 is a computer including one or more processors, a memory, an input/output interface, and a communication interface, which are not illustrated. The one or more processors are one or a combination of a central processing unit (CPU), a graphics processing unit (GPU), an application specific integrated circuit (ASIC), a field-programmable gate array (FPGA), a circuit including multiple discrete semiconductors, and the like, and execute a program stored in the memory. The memory includes a nonvolatile memory and a volatile memory (for example, a compact disc, a digital versatile disc (DVD), a hard disk, a flash memory, or the like), and forms a storage unit of the controller 90.

The controller 90 controls each component of the film deposition apparatus 1 to control the operation of receiving the substrate W from the transfer arm 14a (FIG. 2) to each stage 211, the substrate processing performed on each substrate W, the operation of delivering the substrate W from each stage 211 to the transfer arm 14a, and the like. For example, in the operation of receiving the substrate W, the controller 90 disposes the stage 211 on which the substrate W is to be mounted at the transfer port 14 of the vacuum chamber 11. Then, the controller 90 advances the transfer arm 14a from the transfer port 14 and operates the lift pin mechanism 30 disposed at a position adjacent to the transfer port 14 to raise the lift pins 31 from the stage 211 to receive the substrate W. After the transfer arm 14a is retracted, the lift pins 31 are lowered to mount the substrate W on the stage 211. When the substrate W is being mounted, the gas suctioning section 45 applies a suction force to the substrate W to the mounting surface 211s to assist the mounting of the substrate W. Additionally, the controller 90 sequentially changes a stage 211 adjacent to the transfer port 14 by the rotation of the rotary table 21 to mount the substrate W on each stage 211.

When the substrate processing is performed, the controller 90 reduces the pressure in the vacuum chamber 11 to a predetermined internal pressure and heats each substrate W by the heating section 15. Further, the controller 90 rotates each stage 211 about the rotation shaft 212 while rotating the rotary table 21 about the rotary shaft 23. In this state, a desired film is deposited on the surface of each substrate W by supplying a source gas from the source gas nozzle 121 of the gas introduction section 12, supplying a reactive gas from the reactive gas nozzle 122, and supplying a separation gas from the separation gas nozzles 123 and 124.

In the operation of delivering the substrate W after the substrate processing, the controller 90 disposes the stage 211 from which the substrate W is to be delivered at the transfer port 14 of the vacuum chamber 11, and raises the lift pins 31 from the stage 211 to raise the substrate W. After the transfer arm 14a enters, the controller 90 lowers the lift pins 31 to deliver the substrate W to the transfer arm 14a. With this, the transfer arm 14a carries out the substrate W from the vacuum chamber 11.

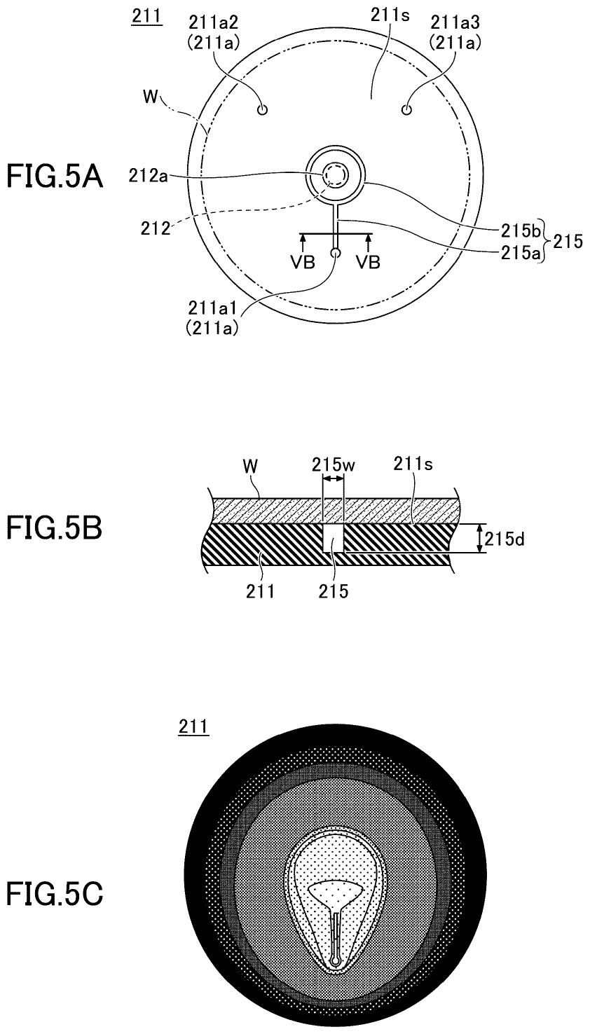

Here, in the operation of receiving the substrate W, the film deposition apparatus 1 can apply a suction force (a negative pressure) to the through-hole 211a located on the outer peripheral side of the rotary table 21 by the gas suctioning section 45 (see FIG. 4) in a state where the cylindrical member 48 is in contact with the stage 211. Hereinafter, among the multiple through-holes 211a of the stage 211, one through-hole located on the outer peripheral side of the rotary table 21 is also referred to as a through-hole 211al, and two through-holes located on the central side of the rotary table 21 are also referred to as through-holes 211a2 and 211a3 (see FIG. 5A).

That is, in the film deposition apparatus 1, when the lift pin 31 is being lowered, the through-hole 211al of the stage 211 and the gas path 111a provided in the main body 111 communicate with each other via the internal space of the cylindrical member 48, the accommodation space 42a of the accommodating part 41, the arrangement hole 43a, and the gas communication hole 43b. With this configuration, when the lift pins 31 are being lowered, the substrate W supported by the lift pins 31 can receive the suction force of the suction pump 46 of the gas suctioning section 45 from the through-holes 211al.

However, the above-described film deposition apparatus 1 applies the suction force to only one through-hole 211al located on the outer peripheral side of the rotary table 21 at the position adjacent to the transfer port 14. This is because it is difficult to cause the gas path 111a to communicate with the two through-holes 211a2 and 211a3 located on the center side of the rotary table 21 due to other structures (the heating section 15, the rotation shaft 212, and the like).

If a structure in which the substrate W is suctioned by only one through-hole 211al is adopted, the suction force applied to the substrate W is not sufficiently strong, and the suction force is applied only to a local portion of the substrate W. Therefore, when the substrate W is mounted on the stage 211, the substrate W may slip.

In the film deposition apparatus 1 according to the present embodiment, in order to stably and accurately mount the substrate W on the stage 211, a groove 215 is formed to be continuous with the through-hole 211al communicating with the gas suctioning section 45. The groove 215 is continuously open on the mounting surface 211s and faces the substrate W mounted on the mounting surface 211s. With this, in the film deposition apparatus 1, the suction force of the gas suctioning section 45 is also exerted from the through-hole 211a to the groove 215, and the substrate W can be suctioned by both the through-hole 211a and the groove 215.

FIG. 5A is a plan view of the stage 211. FIG. 5B is a cross-sectional view taken along the line VB-VB of FIG. 5A. FIG. 5C is a diagram illustrating a distribution of the suction force applied on the mounting surface 211s of the stage 211. The groove 215 according to the present embodiment communicates with the through-hole 211al located on the outer peripheral side of the rotary table 21 and extends toward the center of the stage 211 from the through-hole 211al. Here, “extend toward the center” in the present disclosure indicates that the groove 215 extends to inside a virtual circle having a radius being a length from the center of the stage 211 to the through-hole 211a. Here, the rotation shaft 212 is connected to the center of the stage 211, and a cap 212a covering the rotation shaft 212 is fitted into the center of the mounting surface 211s. The upper surface of the cap 212a is flush with the surrounding surface and forms the mounting surface 211s.

Specifically, the groove 215 has a line segment groove 215a communicating with the through-hole 211al and an annular groove 215b communicating with the line segment groove 215a. The line segment groove 215a linearly extends along the radial direction connecting the through-hole 211al to the center of the stage 211. One end of the line segment groove 215a communicates with the side of the through-hole 211al, while the other end of the line segment groove 215a communicates with the side of the annular groove 215b. The total length of the line segment groove 215a depends on the diameter of the mounting surface 211s. For example, when the diameter of the mounting surface 211s is 300 mm, the total length may be set in a range of about 30 mm to 100 mm.

The annular groove 215b forms a circle (extends) at positions spaced apart from the center of the stage 211 (the cap 212a) by the same radius. The diameter of the annular groove 215b depends on the diameter of the mounting surface 211s. For example, when the diameter of the mounting surface 211s is 300 mm, the diameter of the annular groove 215b may be set in a range of about 60 mm to 100 mm.

The groove 215 (the line segment groove 215a and the annular groove 215b) is formed in a rectangular shape in which a groove depth 215d is longer than a groove width 215w in the cross-sectional view illustrated in FIG. 5B. Although depending on the size of the stage 211, the actual size of the groove width 215w may be set in a range of, for example, about 0.5 mm to 2.5 mm. Although depending on the thickness of the stage 211, the actual size of the groove depth 215d may be set in a range of about 1 mm to 3 mm, for example.

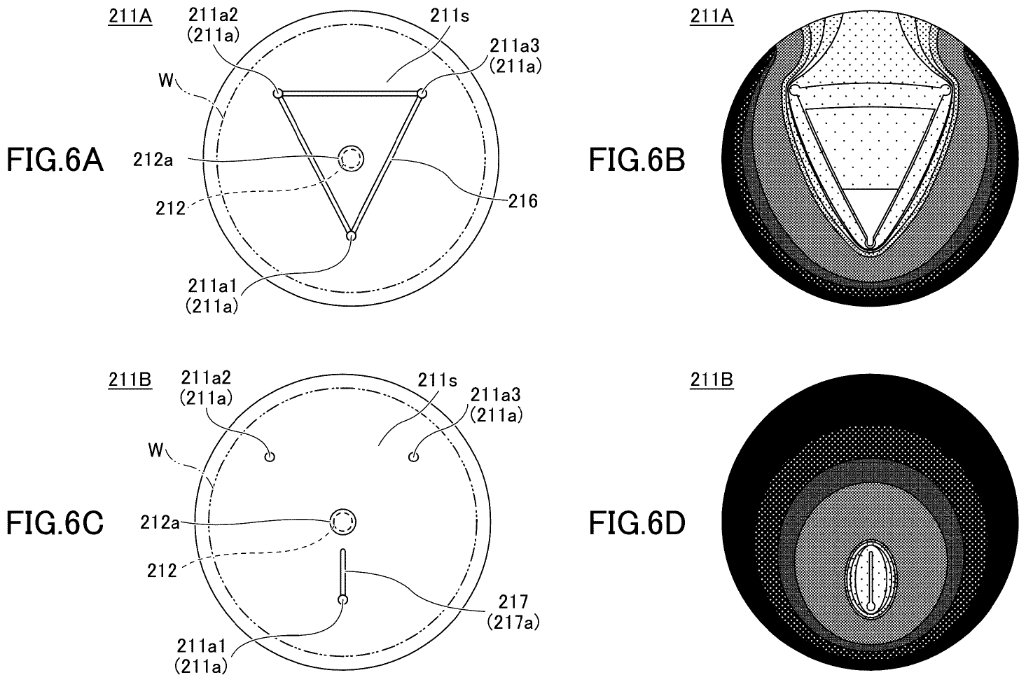

The stage 211 having the groove 215 described above can suction the substrate W with a suction force as illustrated in FIG. 5C. In FIG. 5C (and FIG. 6B and FIG. 6D described later), the suction force is indicated by multiple gradations between white and black, and the suction force increases as the color approaches white and decreases as the color approaches black. In the stage 211, the suction force is strongest at the through-hole 211al, which is closest to the space communicating with the suction pump 46, and an area in the line segment groove 215a that is close to the through-hole 211al. In the vicinity of the groove 215, the suction force is the next strongest. Therefore, the groove 215 having the line segment groove 215a and the annular groove 215b can apply a strong suction force throughout a wide range around the center of the mounting surface 211s (a range slightly spaced apart from the annular groove 215b to the outer side in the radial direction). Additionally, the suction force transmitted from the groove 215 is further concentrically transmitted to the surrounding thereof, and a certain degree of the suction force can be applied to the outer peripheral side of the stage 211.

Here, if the groove 215 is not provided and the suction force is applied to the substrate W by one through-hole 211al, the suction force is applied concentrically around the through-hole 211al. Therefore, for example, the suction force of the through-hole 211al is not appreciably transmitted to a position spaced apart from the through-hole 211al further than the center of the mounting surface 211s (the vicinity of the other through-holes 211a2 and 211a3, and the like). That is, the suction force on the substrate W by one through-hole 211al is weak.

As an example, the suction force on the substrate W by one through-hole 211al was simulated when the internal pressure of the vacuum chamber 11 was set to 6.7 Torr (≈893 Pa) and the suction pressure of the suction pump 46 of the gas suctioning section 45 was set to −0.5 Torr (≈−66.7 Pa). As a result of this simulation, the suction force applied to the substrate W is 3.8 N. If the substrate W is suctioned by one through-hole 211al in such a way, the suction force is weak, and the substrate W may slip when the substrate W is mounted on the stage 211.

With respect to the above, in the film deposition apparatus 1 according to the present embodiment, the groove 215 communicates with one through-hole 211al, so that, as illustrated in FIG. 5C, the substrate W can be suctioned at a position close to the center of the mounting surface 211s, and the suction force of the mounting surface 211s can be spread. For example, as in the above description, the suction force on the substrate W by one through-hole 211al and the groove 215 was simulated when the internal pressure of the vacuum chamber 11 was set to 6.7 Torr and the suction pressure of the suction pump 46 of the gas suctioning section 45 was set to −0.5 Torr. As a result of this simulation, the suction force applied to the substrate W is 13.4 N. That is, by forming the groove 215 as illustrated in FIG. 5A, a strong suction force can be applied to the substrate W. As a result, when the substrate W is mounted on the stage 211, the film deposition apparatus 1 can prevent the substrate W from slipping and can stably mount the substrate W on the stage 211.

Here, the substrate processing apparatus (the film deposition apparatus 1) according to the present disclosure is not limited to the above-described embodiment, but may be modified in various ways. For example, although the film deposition apparatus 1 is configured to rotate each stage 211 around the rotation shaft 212 in the above-described embodiment, each stage 211 may be non-rotatably fixed to the rotary table 21 and may be configured to revolve only by the rotation of the rotary table 21. Also in this case, the structure in which the suction force is applied when the substrate W is mounted on each stage 211 is the through-hole 211al on the outer peripheral side of the rotary table 21, and the suction force is not easily applied to the other through-holes 211a2 and 211a3. Therefore, by causing the groove 215 to communicate with the through-hole 211al, with which the gas suctioning section 45 communicates, the suction force to the substrate W can also be increased.

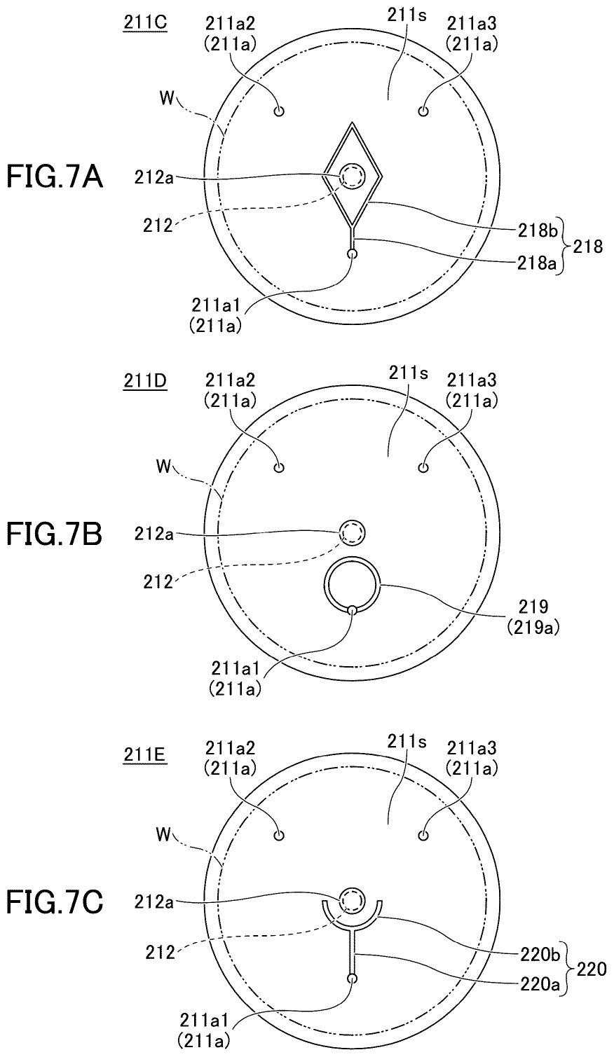

Additionally, the shape of the groove 215 is not limited to the example illustrated in FIG. 5. The suction force to the substrate W can be increased as long as the groove 215 extends from the through-hole 211al toward the center of the stage 211. In the following, some examples of other grooves 215 will be described with reference to FIGS. 6A, 6B, 6C, 6D, 7A, 7B, and 7C.

A stage 211A according to a first modified example illustrated in FIG. 6A is different from the above-described groove 215 in that three through-holes 211a communicate with each other by a groove 216. That is, similarly with the above, the groove 216 extends from the through-hole 211al toward the center of the stage 211, but, differently from the above, linearly extends toward the other through-holes 211a2 and 211a3 without passing through the center. Additionally, the groove 216 linearly extends between the through-hole 211a2 and the through-hole 211a3.

As described above, even in the groove 216 connecting the multiple through-holes 211a to each other, as illustrated in FIG. 6B, the distribution of the suction force can be spread over the entire mounting surface 211s. For example, in a simulation in which the internal pressure of the vacuum chamber 11 was set to 6.7 Torr and the suction pressure of the suction pump 46 of the gas suctioning section 45 was set to −0.5 Torr, the suction force applied to the substrate W was 26.1 N. Therefore, the stage 211A having the groove 216 can fix the substrate W with a stronger suction force.

A stage 211B according to a second modified example illustrated in FIG. 6C is different from the above-described grooves 215 and 216 in that only the line segment groove 215a is applied as a groove 217 communicating with the through-hole 211al. That is, the groove 217 linearly extends for a short distance from the through-hole 211al toward the center of the stage 211.

Even with such a groove 217, as illustrated in FIG. 6D, the suction force can be spread so as to draw an ellipse having the groove 217 as a base point. For example, in a simulation in which the internal pressure of the vacuum chamber 11 was set to 6.7 Torr and the suction pressure of the suction pump 46 of the gas suctioning section 45 was set to −0.5 Torr, the suction force applied to the substrate W was 7.4 N. Therefore, even in the stage 211B having the groove 216, the substrate W can be fixed with a stronger suction force in comparison with the case where the substrate W is suctioned only by the through-hole 211al.

In a groove 218 of a stage 211C according to a third modified example illustrated in FIG. 7A, a diamond-shaped polygonal groove 218b communicates with a line segment groove 218a communicating with the through-hole 211al. Even in this case, the stage 211C can apply the same degree of the suction force as the groove 215 (see FIG. 5A) to the substrate W.

In a groove 219 of a stage 211D according to a fourth modified example illustrated in FIG. 7B, an annular groove 219a directly communicates with the through-hole 211al. Even in this case, the stage 211D can apply a strong suction force to the substrate W.

In a groove 220 of a stage 211E according to a fifth modified example illustrated in FIG. 7C, a semicircular arc groove 220b communicates with a line segment groove 220a communicating with the through-hole 211al. Even in this case, the stage 211E can apply a strong suction force to the substrate W.

The technical idea and effects of the present disclosure described in the above embodiments will be described below.

The substrate processing apparatus (the film deposition apparatus 1) according to an aspect of the present disclosure includes the vacuum chamber 11, the rotary table 21 rotatably provided in the vacuum chamber 11, the stage 211 having the mounting surface 211s on which the substrate W is mounted at a position spaced apart from the rotation center of the rotary table 21, the lift pin 31 that is displaced relative to the stage 211 through the through-hole 211a of the stage 211 to raise and lower the substrate W, and the gas suctioning section 45 configured to apply the suction force to the substrate W via the through-hole 211a when the lift pin 31 is being lowered. The stage 211 includes one of the grooves 215 to 220 communicating with the through-hole 211a and extending from the through-hole 211a toward the center of the stage 211 on the mounting surface 211s of the stage 211.

According to the above, in the substrate processing apparatus (the film deposition apparatus 1), the distribution of the suction force on the mounting surface 211s can be spread by the groove 215 communicating with the through-hole 211a, and the suction force on the substrate W can be increased. This allows the substrate processing apparatus to stably and accurately mount the substrate on the stage 211, and as a result, the substrate processing can be satisfactorily performed.

Additionally, the grooves 215, 217, 218, and 220 have portions linearly extending from the through-hole 211a toward the center of the stage 211. This allows the substrate processing apparatus (the film deposition apparatus 1) to easily spread the distribution of the suction force toward the center of the mounting surface 211s, thereby stably fixing the substrate W at the vicinity of the center of the substrate W.

Additionally, the grooves 215 and 220 have one or more portions that communicate with the linearly extending portions and forms a circle or an arc at a position spaced apart from the center of the stage. This allows the substrate processing apparatus (the film deposition apparatus 1) to spread the distribution of the suction force from the center of the mounting surface 211s, thereby fixing the substrate W in a wide range around the center of the substrate W more firmly.

Additionally, the circular or arc-shaped portion is formed in an annular shape. This allows the substrate processing apparatus (the film deposition apparatus 1) to concentrically spread the suction force from the center of the mounting surface 211s.

Additionally, the stage 211 rotates relative to the rotary table 21. The substrate processing apparatus (the film deposition apparatus 1) can stably mount the substrate W on the stage 211 even when the stage 211 rotates with respect to the rotary table 21.

Additionally, the substrate processing apparatus includes the accommodating part 41 that accommodates the lift pin 31 and the cylindrical member 48 that is raised together with the lift pin 31 relative to the accommodating part 41 on the back surface of the stage 211 and comes into contact with the stage 211 when the substrate W is mounted on the stage 211. The gas suctioning section 45 transmits the suction force to the through-hole 211a and the grooves 215 to 220 through the inside of the accommodating part 41 and the inside of the cylindrical member 48. This allows the substrate processing apparatus (the film deposition apparatus 1) to stably secure a transmission path of the suction force from the gas suctioning section 45 to the mounting surface 211s.

Additionally, the gas suctioning section 45 is connected to the outer peripheral portion of the vacuum chamber 11 and transmits the suction force to the through-hole 211a disposed on the outer peripheral side of the rotary table 21 among the multiple through-holes 211al formed in the stage 211. This allows the substrate processing apparatus (the film deposition apparatus 1) to obtain a strong suction force even in a structure in which suction is performed from the outer peripheral portion of the vacuum chamber 11 to the stage 211 of the rotary table 21.

The substrate processing apparatuses according to the embodiments disclosed herein are illustrative in all respects and are not restrictive. The embodiments can be modified and improved in various forms without departing from the scope and spirit of the appended claims. The matters described in the above-described embodiments can also take other configurations as long as there is no contradiction, and can be combined as long as there is no contradiction.

According to the aspect, a substrate can be stably mounted on a stage of a rotary table.

What is claimed is:

1. A substrate processing apparatus comprising:
a vacuum chamber;
a rotary table rotatably provided in the vacuum chamber;
a stage having a mounting surface on which a substrate is mounted at a position spaced apart from a rotation center of the rotary table;
a lift pin configured to be displaced relative to the stage through a through-hole of the stage to raise and lower the substrate; and
a gas suctioning section configured to apply a suction force to the substrate via the through-hole when the lift pin is being lowered,
wherein the stage includes a groove on the mounting surface, the groove communicating with the through-hole and extending from the through-hole toward a center of the stage.

2. The substrate processing apparatus as claimed in claim 1, wherein the groove includes a portion linearly extending from the through-hole toward the center of the stage.

3. The substrate processing apparatus as claimed in claim 2, wherein the groove includes a portion communicating with the linearly extending portion and forming a circle or an arc at a position spaced apart from the center of the stage.

4. The substrate processing apparatus as claimed in claim 3, wherein the portion forming the circle or the arc is formed in an annular shape.

5. The substrate processing apparatus as claimed in claim 1, wherein the stage rotates relative to the rotary table.

6. The substrate processing apparatus as claimed in claim 1, further comprising:
an accommodating part configured to accommodate the lift pin; and
a cylindrical member configured to be raised together with the lift pin on a back surface of the stage relative to the accommodating part and to come into contact with the stage when the substrate is mounted on the stage,
wherein the gas suctioning section transmits the suction force to the through-hole and the groove via an inside of the accommodating part and an inside of the cylindrical member.

7. The substrate processing apparatus as claimed in claim 6, wherein the gas suctioning section is connected to an outer peripheral portion of the vacuum chamber and transmits the suction force to the through-hole disposed on an outer peripheral side of the rotary table among a plurality of said through-holes formed in the stage.
